(19) United States
(12) Patent Application Publication
(10) Pub. No.: US 2024/0188340 A1
(43) Pub. Date: Jun. 6, 2024

(54) DISPLAY DEVICES

(71) Applicant: InnoLux Corporation, Miao-Li County (TW)

(72) Inventors: Chiao-Han CHANG, Miao-Li County (TW); Mei-Chi HSU, Miao-Li County (TW); Chung-Wen YEN, Miao-Li County (TW)

(21) Appl. No.: 18/500,354

(22) Filed: Nov. 2, 2023

(30) Foreign Application Priority Data
Dec. 2, 2022 (CN) 202211541195.1

(51) Int. Cl. H10K 59/122; H10K 59/35

(52) U.S. Cl. CPC H10K 59/122; H10K 59/353

(57) ABSTRACT

Display devices are provided. The display device includes a substrate, first to third light emitting units, and first and second spacers disposed on the substrate. The first to third light emitting units are configured to emit a first light with a first color respectively. The first light emitting unit is adjacent to the second and third light emitting units. The first spacer is disposed between the first light emitting unit and the second light emitting unit. The second spacer is disposed between the first light emitting unit and the third light emitting unit. The extending line of the first long axis of the first spacer passes through the first light emitting unit and the second light emitting unit. The extending line of the second long axis of the second spacer passes through the first light emitting unit and the third light emitting unit.

### CROSS REFERENCE TO RELATED APPLICATIONS

This application claims priority of China Patent Application No. CN 202211541195.1, filed on Dec. 2, 2022, the entirety of which is incorporated by reference herein.

### TECHNICAL FIELD

Some embodiments of the present disclosure relate to display devices, and, in particular, to display devices that include a first spacer and a second spacer.

### BACKGROUND

An electronic device (such as, a display device) usually includes a substrate and a spacer disposed on the substrate. Thus, the spacer provides support. However, current spacers suffer from the problem of being unevenly arranged, meaning that they cannot provide uniform support.

### SUMMARY

In some embodiments, a display device is provided. The display device includes a substrate, a first light emitting unit, a second light emitting unit, a third light emitting unit, a first spacer, and a second spacer. The first light emitting unit, the second light emitting unit, and the third light emitting unit are disposed on the substrate and configured to emit a first light with a first color respectively. The first light emitting unit is adjacent to the second light emitting unit and the third light emitting unit. The first spacer is disposed on the substrate. The second spacer is disposed on the substrate. In a top view of the display device, the first spacer is disposed between the first light emitting unit and the second light emitting unit, the second spacer is disposed between the first light emitting unit and the third light emitting unit, an extending line of a first long axis of the first spacer passes through the first light emitting unit and the second light emitting unit, and an extending line of a second long axis of the second spacer passes through the first light emitting unit and the third light emitting unit.

In some embodiments, a display device is provided. The display device includes a substrate, a first light emitting unit, a second light emitting unit, a third light emitting unit, a first spacer, and a second spacer. The first light emitting unit, the second light emitting unit, and the third light emitting unit are disposed on the substrate and configured to emit a light with a first color respectively. The first light emitting unit is adjacent to the second light emitting unit and the third light emitting unit. The first spacer is disposed on the substrate. The second spacer is disposed on the substrate. In a top view of the display device, the first spacer is disposed between the first light emitting unit and the second light emitting unit, the second spacer is disposed between the first light emitting unit and the third light emitting unit, the first light emitting unit and the second light emitting unit are arranged along a first direction, and the first light emitting unit and the third light emitting unit are arranged along a second direction different from the first direction.

The display device of the present disclosure may be applied in various types of electronic devices. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 shows a schematic top view of a display device according to some embodiments of the present disclosure.

FIG. 2 shows a schematic view of the long axis of different spacers according to some embodiments of the present disclosure.

FIG. 3 shows a schematic top view and a schematic cross-sectional view of a display device according to some embodiments of the disclosure.

FIG. 4 shows a schematic view of the centers of different light emitting units according to some embodiments of the present disclosure.

FIG. 5A shows a schematic top view of a display device according to some embodiments of the present disclosure.

FIG. 5B shows a schematic cross-sectional view of a display device according to some embodiments of the present disclosure.

FIG. 6 shows a schematic top view of a display device according to some embodiments of the disclosure.

FIG. 7 shows a schematic top view of a display device according to some embodiments of the present disclosure.

FIG. 8 shows a schematic top view of a display device according to some embodiments of the present disclosure.

### DETAILED DESCRIPTION

The following disclosure provides many different embodiments or examples for implementing different features of display devices disclosed herein. Specific examples of each feature and its configuration are described below to simplify the embodiments of the present disclosure. Naturally, these are examples and are not intended to limit the present disclosure. For example, if the description mentions that the first feature is formed on the second element, it may include an embodiment in which the first feature and second feature are in direct contact, or may include an embodiment in which additional feature is formed between the first feature and the second feature thereby the first feature and the second feature do not directly contact. Furthermore, the embodiments of the present disclosure may repeat reference numerals and/or characters in different examples. This repetition is for brevity and clarity and is not intended to represent a relationship between the different embodiments and/or aspects discussed herein.

Orientation terms discussed herein, such as “up”, “down”, “front”, “rear”, “left”, “right”, and the like, are only referring to the direction of the drawings. Accordingly, the used orientation terms are intended to illustrate rather than limit the disclosure.

In some embodiments of the present disclosure, terms related to bonding and connection, such as “connect”, “interconnect”, and the like, unless otherwise defined, may refer to two structures in direct contact, or they may refer to two structures that are not in direct contact, there being another structure disposed between the two structures. Terms related to bonding and connection may also include embodiments in which both structures are movable, or both structures are fixed. Furthermore, the terms “electrically connect” or “electrically couple” include direct and indirect means of electrical connection.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms. Accordingly, a first element in the specification may be a second element in the claim. The terms “about”, “equal”, “same”, “essentially”, “substantially”, “approximately”, and the like generally mean within 20% of a given value or range, or mean within 10%, within 5%, within 3%, within 2%, within 1%, or within 0.5% of a given value or range.

Furthermore, any two values or directions used for comparison may have certain tolerance. If the first value is equal to the second value, this implies that there may be a tolerance within about 10% between the first value and the second value. If the first direction is perpendicular to or “substantially” perpendicular to the second direction, the angle between the first direction and the second direction may be between 80 degrees and 100 degrees. If the first direction is parallel to or “substantially” parallel to the second direction, the angle between the first direction and the second direction may be between 0 degrees and 10 degrees.

Unless otherwise defined, all terms (including technical and scientific terms) used herein have the same meaning as commonly understood by a person of ordinary skills in the art. It should be understand that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Some variations of the embodiments are described below. Similar reference numerals are used to designate similar elements in the different drawings and illustrated embodiments. It will be appreciated that additional operations may be provided before, during, and after the method, and that some of the described operations may be replaced or deleted for other embodiments of the method.

It should be understood that, according to the embodiments of the present disclosure, an optical microscope (OM), a scanning electron microscope (SEM), a film thickness profilometer (type: α-step), ellipsometry, or another suitable method may be used to measure the depth, thickness, width, or height of each element, pitch, space, or distance between elements. According to some embodiments, a scanning electron microscope may be used to obtain an image of a cross-sectional structure, including the elements to be measured, and the depth, thickness, width, or height of each element in the image may be measured, or the pitch, space, or distance between elements in the image may be measured.

In some embodiments, the electronic device may include a display device, a back light device, an antenna device, a sensing device, or a tiled device, but the present disclosure is not limited thereto. The electronic device may be a foldable or flexible electronic device. The display device may be a non-self-luminous display device or a self-luminous display device. The antenna device may be a liquid-crystal antenna device or a non-liquid-crystal antenna device. The sensing device may be a sensing device for sensing capacitance, light, heat, or ultrasonic waves, but the present disclosure is not limited thereto. The electronic elements may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling device may be, for example, a display titling device or an antenna titling device, but the present disclosure is not limited thereto. It should be noted that, the electronic device may be any arrangement and combination of the foregoing, but the present disclosure is not limited thereto. The content of the present disclosure will be described below with a display device as an electronic device or a tiled device, but the present disclosure is not limited thereto.

In addition, the shape of the electronic device may be rectangular, circular, polygonal, a shape with curved edges, or another suitable shape. The electronic device may have a peripheral system, such as a processing system, a driving system, a controlling system, a light source system, a shelf system, or the like to support the electronic device or the tiled device.

It should be noted that, the electronic device may be any arrangement and combination of the foregoing, but the present disclosure is not limited thereto. It should be noted that in the following embodiments, without departing from the spirit of the present disclosure, features in several different embodiments may be replaced, reorganized, and combined to complete other embodiments. As long as the features of the various embodiments do not violate the spirit of the present disclosure or conflict with each other, they may be combined arbitrarily.

Unless otherwise defined, all terms (including technical and scientific terms) used herein have the same meaning as commonly understood by a person of ordinary skills in the art. It should be understand that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

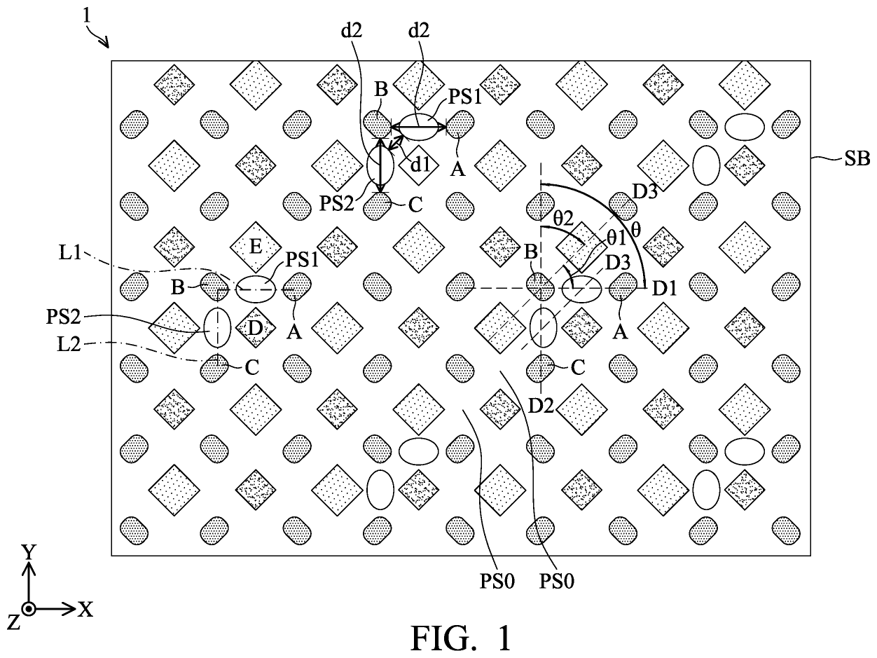

FIG. 1 shows a schematic top view of a display device 1 according to some embodiments of the present disclosure. It should be understood that, for the sake of clarity, some elements of the display device 1 are omitted in the drawings, and some elements are schematically shown. In some embodiments, additional elements may be added to the display device 1 described below. In other embodiments, some elements of the display device 1 described below may be replaced or omitted. It should be understood that, in some embodiments, additional operation steps may be provided before, during and/or after the method of forming the display device 1. In some embodiments, some of the described operation steps may be replaced or omitted, and the order of some of the described operation steps is interchangeable.

As shown in FIG. 1A, in some embodiments, the display device 1 may include a substrate SB. In some embodiments, the substrate SB may include a foldable substrate, a flexible substrate, a rigid substrate, or a combination thereof, but the present disclosure is not limited thereto. In some embodiments, the substrate SB may include glass, quartz, sapphire, ceramics, polyimide (PI), polycarbonate (PC), polyethylene terephthalate (PET), polypropylene (PP), other suitable materials, or a combination thereof, but the present disclosure is not limited thereto. In some embodiments, the substrate SB may include a transparent substrate, a semi-transparent substrate, or an opaque substrate.

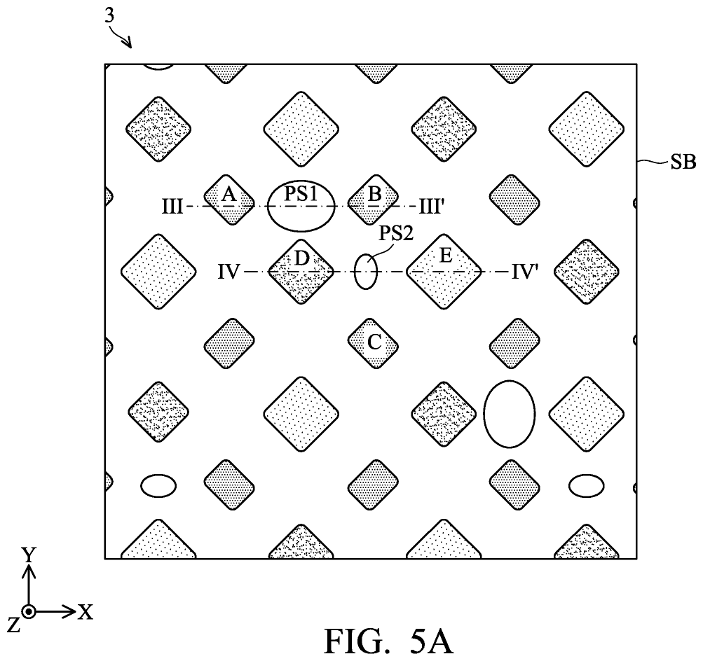

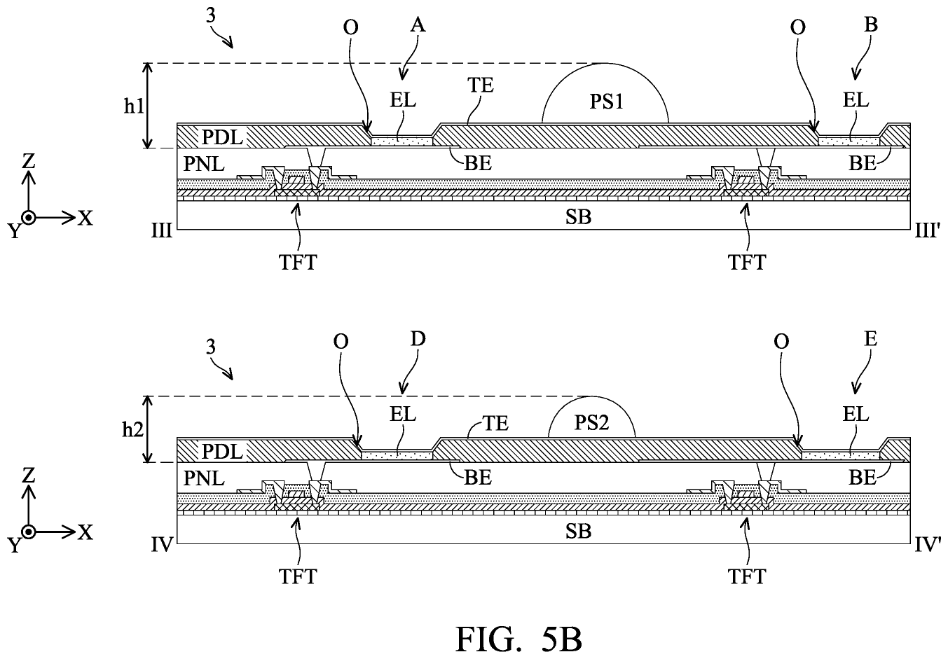

As shown in FIG. 1, in some embodiments, the display device 1 may include a light emitting unit for emitting light. In some embodiments, the light emitting unit may include an organic light emitting diode unit, a mini light emitting diode unit, a micro light emitting diode unit, or a quantum dot light emitting diode unit, but the present disclosure is not limited thereto. In some embodiments, according to usage requirements, the light emitting units may respectively emit lights with different colors. For example, the light emitting unit may emit red light, green light, blue light, or a combination thereof, but the present disclosure is not limited thereto. In some embodiments, the shape of the light emitting unit may be circular, elliptical, rectangular (with or without arc corners), polygonal, irregular, or another suitable shape, but the present disclosure is not limited thereto. In some embodiments, the shape and size of the light emitting unit may be defined by the shape and size of the opening of the pixel defining layer (for example, the pixel defining layer PDL shown in FIG. 5B). In some embodiments, the light emitting units of different colors may be repeatedly arranged on the substrate SB in a specific order, such as PenTile arrangement, but the present disclosure is not limited thereto.

In some embodiments, the display device 1 may include a first light emitting unit B, a second light emitting unit A, and a third light emitting unit C disposed on the substrate SB. In some embodiments, the first light emitting unit B, the second light emitting unit A, and the third light emitting unit C are configured to emit first light with a first color respectively. For example, the first color may be blue, but the present disclosure is not limited thereto. As shown in FIG. 1, the first light emitting unit B is adjacent to the second light emitting unit A and the third light emitting unit C. It should be noted that, herein, a light emitting unit being “adjacent” to another light emitting unit means that there is no other light emitting unit between the light emitting unit and the other light emitting unit.

As shown in FIG. 1, in some embodiments, the display device 1 may include a first spacer PS1 and a second spacer PS2 disposed on the substrate SB. In some embodiments, the first spacer PS1 and/or the second spacer PS2 may include organic materials, inorganic materials, photoresist materials, elastic materials, the like, or another suitable spacer material, but the present disclosure is not limited thereto. In some embodiments, the materials of the first spacer PS1 and the second spacer PS2 may be the same or different. In some embodiments, in the top view of the display device, the profile shape of the first spacer PS1 and/or the second spacer PS2 may be circular, oval, triangular, rectangular, polygonal, L-shaped, irregular, other suitable shapes, but the present disclosure is not limited thereto.

As shown in FIG. 1, in some embodiments, in the top view of the display device 1, the first spacer PS1 may be disposed between the first light emitting unit B and the second light emitting unit A, and the second spacer PS2 may be disposed between the first light emitting unit B and the third light emitting unit C. In some embodiments, the extending line L1 of the first long axis of the first spacer PS1 may substantially pass through the first light emitting unit B and the second light emitting unit A, and the extending line L2 of the second long axis of the second spacer PS2 may substantially pass through the first light emitting unit B and the third light emitting unit C.

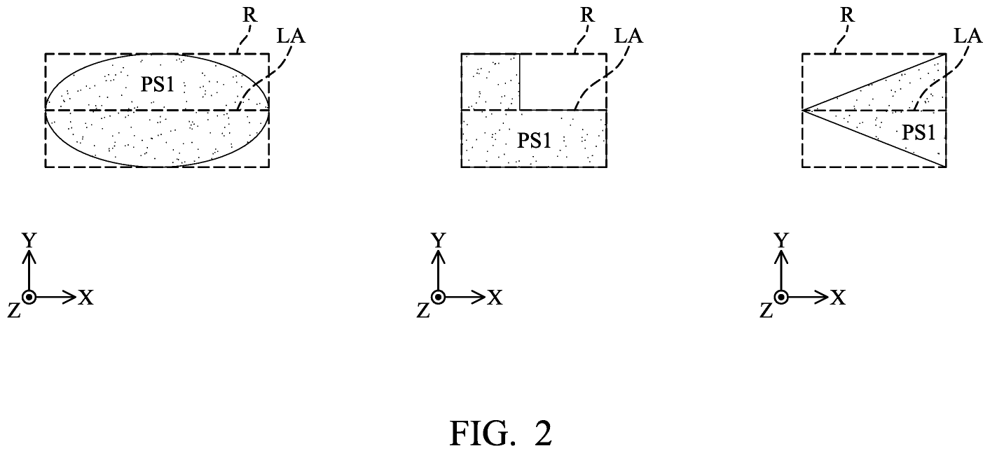

In detail, the definition of the “long axis” described herein will be described with reference to FIG. 1 and FIG. 2. FIG. 2 shows a schematic view of the long axis of different spacers according to some embodiments of the present disclosure. As shown in FIG. 2, the first spacer PS1 with different profile shapes is used as an example for illustration of the definition of the “long axis”. Moreover, the corresponding long axis of the second spacer PS2 and other spacers (for example, the third spacer PS3 and the fourth spacer PS4) described below may be defined similarly. In some embodiments, the first spacer PS1 may have a first long axis, the second spacer PS2 may have a second long axis, the third spacer PS3 described below may have a third long axis, and the fourth spacer PS4 described below may have a fourth long axis. As shown in FIG. 2, in some embodiments, when the first spacer PS1 is elliptical, a smallest rectangle R capable of covering the first spacer PS1 may be framed. The smallest rectangle R may have a pair of long sides and a pair of short sides. An imaginary line (as a dotted line in FIG. 2) is drawn in which the imaginary line is parallel to the long side of the smallest rectangle R and substantially splits the area of the smallest rectangle R in half. Then, the imaginary line may be defined as the first long axis LA of the first spacer PS1. As shown in FIG. 2, in some other embodiments, when the profile shape of the first spacer PS1 is L-shaped or triangular, the first long axis LA of the first spacer PS1 is substantially shown in FIG. 2. The profile shape of the first spacer PS1 and/or the second spacer PS2 may be circular, oval, triangular, rectangular, polygonal, L-shaped, irregular, or another suitable shape.

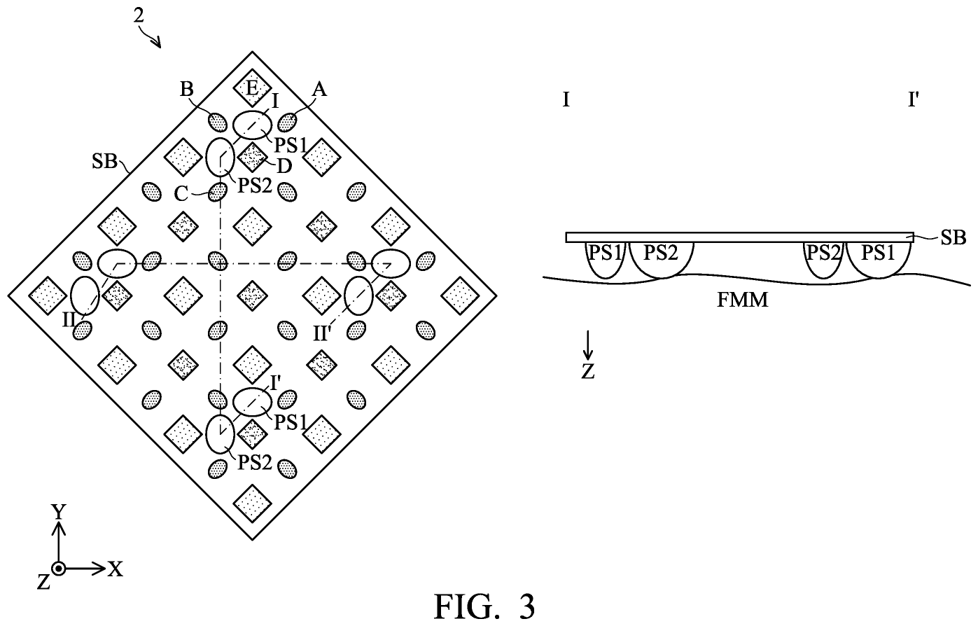

Accordingly, with reference to FIG. 1 and FIG. 2, the extending line L1 of the first long axis of the first spacer PS1 may pass through the first light emitting unit B and the second light emitting unit A, and the extending line L2 of the second long axis of the second spacer PS2 may pass through the first light emitting unit B and the third light emitting unit C. Thus, areas of the first spacer PS1 and/or the second spacer PS2 may be increased in a fixed area of the underlying element (for example, in the fixed area of the pixel defining layer) thereby increasing the supporting force of the first spacer PS1 and/or the second spacer PS2. Moreover, the first spacer PS1 and the second spacer PS2 are disposed between the adjacent first light emitting unit B, the second light emitting unit A, and the third light emitting unit C, so the distance between the first spacer PS1 and the second spacer PS2 may be reduced. At this time, the first spacer PS1 and the second spacer PS2 may be regarded as the same support point. Since the area of the supporting point includes the areas of the first spacer PS1 and the second spacer PS2, the supporting area may be increased without increasing the number of supporting point. In addition, when a mask (such as the fine metal mask FMM in FIG. 3) is subsequently disposed on the first spacer PS1 and the second spacer PS2, the first spacer PS1 and/or the second spacer PS2 may reduce the wrinkles of the mask, reducing the compression of the mask, and/or increasing the flatness of the mask. Therefore, the probability of scratching any layer in the display device 1 by the mask may be reduced, such as reducing the probability of scratching the light emitting unit, but the present disclosure is not limited thereto.

As shown in FIG. 1, in some embodiments, the display device 1 may further include a fourth light emitting unit D and a fifth light emitting unit E disposed on the substrate SB. In some embodiments, the fourth light emitting unit D may emit a second light with a second color, and the second color is different from the first color. For example, the second color may be red. In some embodiments, the fifth light emitting unit E may emit a third light with a third color, and the third color is different from the first color and the second color. For example, the third color may be red or green, but the present disclosure is not limited thereto.

As shown in FIG. 1, in some embodiments, in the top view of the display device 1, the area of the first light emitting unit B may be less than the area of the fourth light emitting unit D, and the area of the first light emitting unit B may be less than the area of the fifth light emitting unit E. In some embodiments, the areas of the first light emitting unit B, the second light emitting unit A, and the third light emitting unit C may be substantially the same. In some embodiments, the direction of the long axis of the second light emitting unit A and the direction of the long axis of the third light emitting unit C may be substantially the same. In some embodiments, the direction of the long axis of the first light emitting unit B is, for example, different from the direction of the long axis of the second light emitting unit A. In some embodiments, the direction of the long axis of the third light emitting unit C is, for example, different from the direction of the long axis of the second light emitting unit A. The areas of the first light emitting unit B, the second light emitting unit A, and the third light emitting unit C are less than the fourth light emitting unit D and/or the fifth light emitting unit E, so the first spacer PS1 is disposed between the first light emitting unit B and second light emitting unit A and the second spacer PS2 is disposed between the first light emitting unit B and the third light emitting unit C. Therefore, the probability of blocking the light emitted from the emitting unit by the first spacer PS1 and/or second spacer PS2 may be reduced and/or the process flexibility of disposing the first spacer PS1 and the second spacer PS2 may be increased. In some embodiments, the area of the fourth light emitting unit D may be the same as or different from the area of the fifth light emitting unit E. In some embodiments, the area of the fourth light emitting unit D may be less or greater than the area of the fifth light emitting unit E. In some embodiments, the first spacer PS1 is disposed between the fourth light emitting unit D and the fifth light emitting unit E. In some embodiments, the second spacer PS2 is disposed between the fourth light emitting unit D and the fifth light emitting unit E.

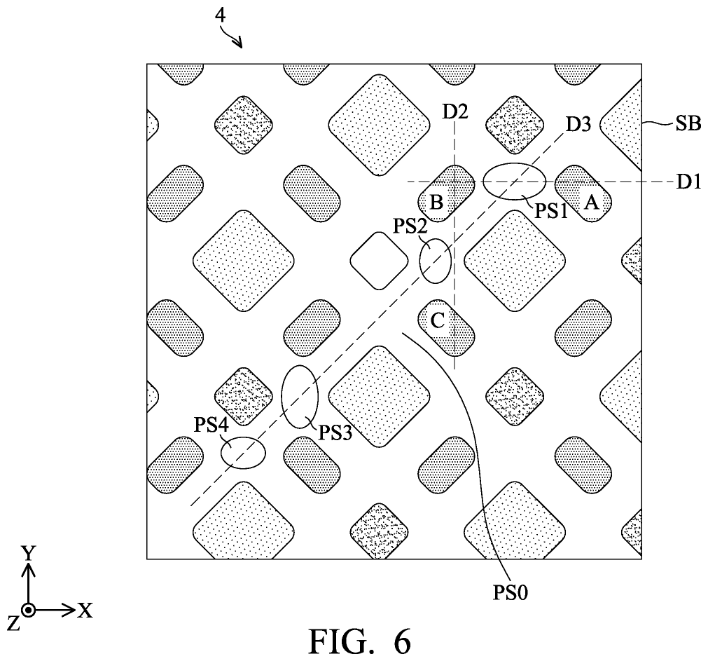

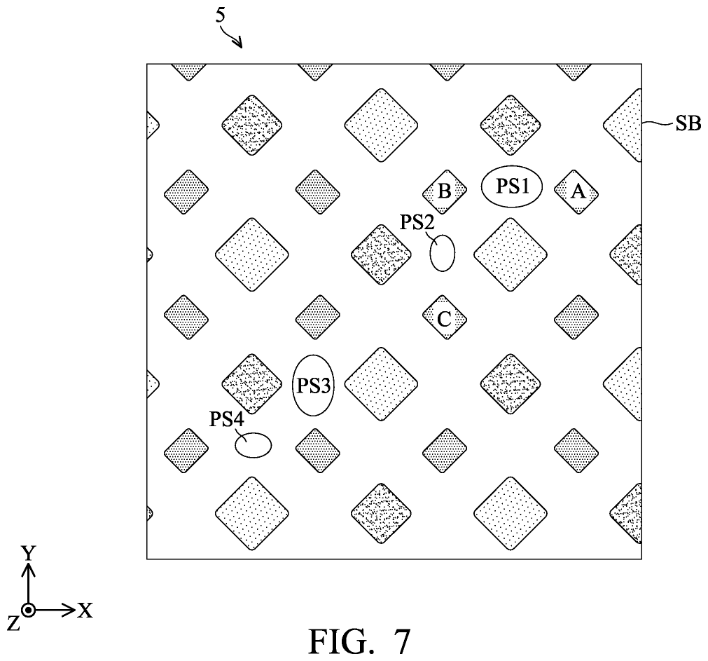

As shown in FIG. 1, in some embodiments, in the top view of the display device 1, the first spacer PS1 and the second spacer PS2 may have substantially the same area, but the present disclosure is not limited thereto. In other embodiments, in the top view of the display device 1, the first spacer PS1 and the second spacer PS2 may have different areas. In some embodiments, the area of the first spacer PS1 may be greater than the area of the second spacer PS2 (for example, as shown in FIG. 5A, FIG. 6, or FIG. 7), but the present disclosure is not limited thereto. In other embodiments, the area of the first spacer PS1 may be less than the area of the second spacer PS2, but the present disclosure is not limited thereto.

As shown in FIG. 1, in some embodiments, in the top view of the display device 1, the minimum distance d1 between the first spacer PS1 and the second spacer PS2 may be less than the minimum distance d2 between the first light emitting unit B and the second light emitting unit A. It should be noted that, in the present disclosure, the “minimum distance” between one component and another component represents the minimum distance between the boundary of the component and the boundary of the other component. Accordingly, since the minimum distance d1 is less than the minimum distance d2, the first spacer PS1 and the second spacer PS2 may be regarded as the same support point. Therefore, the probability of falling the mask in the gap between the first spacer PS1 and the second spacer PS2 during the subsequent disposition of the mask on the display device 1 may be reduced, the wrinkles of the mask may be reduced, and/or the flatness of the mask may be increased.

In some embodiments, the minimum distance d1 between the first spacer PS1 and the second spacer PS2 is greater than 0 and less than 20 um, but the present disclosure is not limited thereto. For example, the minimum distance d1 may be 1 um, 2 um, 3 um, 4 um, 5 um, 6 um, 7 um, 8 um, 9 um, 10 um, 11 um, 12 um, 13 um, 14 um, 15 um, 16 um, 17 um, 18 um, 19 um, 19.9 um, or any value or range of values between the aforementioned values, but the present disclosure is not limited thereto. In some embodiments, when the minimum distance d1 is greater than or equal to 20 um, the distance between the first spacer PS1 and the second spacer PS2 is too large to be regarded as the same support point, thereby improving the probability of falling the subsequently disposed mask between the first spacer PS1 and the second spacer PS2. In other embodiments, the minimum distance d1 between the first spacer PS1 and the second spacer PS2 may be less than the minimum distance d2 between the first light emitting unit B and the third light emitting unit C.

In some embodiments, the minimum distance d2 between the first light emitting unit B and the second light emitting unit A may be greater than or equal to 25 um and less than or equal to 50 um, but the present disclosure is not limited thereto. In some embodiments, the minimum distance d2 between the first light emitting unit B and the third light emitting unit C may be greater than or equal to 25 um and less than or equal to 50 um, but the present disclosure is not limited thereto. For example, the minimum distance d2 may be 25 um, 30 um, 32 um, 35 um, 40 um, 45 um, 50 um, or any value or range of values between the aforementioned values, but the present disclosure is not limited thereto.

FIG. 3 shows a schematic top view of a display device 2 and a schematic cross-sectional view taken along section line I-I′ according to some embodiments of the present disclosure. For the convenience of description, the same or similar elements will not be repeated. As shown in the top view of FIG. 3, in some embodiments, the first light emitting unit B, the second light emitting unit A, and the third light emitting unit C of the display device 2 may be elliptical, but the present disclosure is not limited thereto.

As shown in the schematic cross-sectional view of FIG. 3, in some embodiments, after disposing the first light emitting unit B, the second light emitting unit A, the third light emitting unit C, the first spacer PS1, and the second spacer PS2 on the substrate SB, an evaporation process may be performed on the display device 2, but the present disclosure is not limited thereto. The substrate SB may be turned over such that the substrate SB is upside down to perform the evaporation process. Next, the mask FMM is disposed on the first spacer PS1 and the second spacer PS2, and the first spacer PS1 and the second spacer PS2 may be located between the substrate SB and the mask FMM. In some embodiments, the mask FMM may include a fine metal mask, but the present disclosure is not limited thereto. In some embodiments, the mask FMM may include iron (Fe), nickel (Ni), stainless steel, the like, or another suitable mask material, but the present disclosure is not limited thereto. As shown in the sectional view of FIG. 3 along section line I-I′, since the first spacer PS1 and the second spacer PS2 may be regarded as the same support point, this may reduce the occurrence of wrinkles in the mask FMM and/or increase the flatness of the mask FMM. In addition, during the evaporation process, the mask FMM may absorb heat or receive stress, causing wrinkles to form. Therefore, when the first spacer PS1 and the second spacer PS2 are disposed on the substrate SB, the amount of wrinkles generated in the mask FMM may be reduced. Furthermore, the cross-sectional view taken along section line II-II′ in the schematic top view of FIG. 3 is similar to the cross-sectional view taken along section line I-I′, so the description of the cross-sectional view taken along section line II-II′ is omitted.

As shown in FIG. 1, in some embodiments, in the top view of the display device 1, the first light emitting unit B and the second light emitting unit A are arranged along a first direction D1, and the first light emitting unit B and the third light emitting unit C are arranged along a second direction D2 different from the first direction D1. In some embodiments, an included angle θ between the first direction D1 and the second direction D2 may be in the range of 80 degrees to 100 degrees (for example, perpendicular), but the present disclosure is not limited thereto. For example, the included angle θ may be greater than or equal to 80 degrees and less than or equal to 100 degrees, for example, the included angle θ may be 80 degrees, 82 degrees, 84 degrees, 86 degrees, 88 degrees, 90 degrees, 92 degrees, 94 degrees, 96 degrees, 98 degrees, 100 degrees, or any value or range of values between the aforementioned values, but the present disclosure is not limited thereto.

When the first direction D1 is different from the second direction D2, the first spacer PS1 is disposed between the first light emitting unit B and the second light emitting unit A, and the second spacer PS2 is disposed between the first light emitting unit B and the third light emitting unit C, the directions of the first long axis of the first spacer PS1 and the second long axis of the second spacer PS2 are different. Therefore, since the first spacer PS1 and the second spacer PS2 may be disposed between the adjacent first light emitting unit B, the second light emitting unit A, and the third light emitting unit C which are arranged in different directions, the support area may be increased without increasing supporting point to provide a uniform support effect.

In FIG. 1, in order to illustrate the relationship between the third direction D3 and the first direction D1 and the second direction D2, a dotted line of the third direction D3 is moved up in parallel and the first acute angle θ1 and the second acute angle θ2 are shown in FIG. 1. As shown in FIG. 1, in some embodiments, in the top view of the display device 1, the first spacer PS1 and the second spacer PS2 are arranged along the third direction D3, and the first acute angle θ1 between the first direction D1 and the third direction D3 may be in the range of 40 degrees to 50 degrees. For example, the first acute angle θ1 may be greater than or equal to 40 degrees and less than or equal to 50 degrees, for example, the first acute angle θ1 may be 40 degrees, 42 degrees, 44 degrees, 46 degrees, 48 degrees, 50 degrees, or any value or range of values between the aforementioned values, but the present disclosure is not limited thereto. In some embodiments, the first acute angle θ1 may be about half of the included angle θ, but the present disclosure is not limited thereto. The first spacer PS1 and the second spacer PS2 may be respectively disposed between the adjacent first light emitting unit B, the second light emitting unit A, and the third light emitting unit C which are arranged in different directions, so the support areas of the spacers may be increased without increasing supporting point. Therefore, the spacers may provide a uniform support effect. Moreover, as shown in FIG. 1, in the top view of the display device 1, the first spacer PS1 may be located between the first light emitting unit B and the second light emitting unit A arranged along the first direction D1, and the second spacer PS2 may be located between the first light emitting unit B and the third light emitting unit C arranged in the second direction D2. The supporting effect may be provided in the first direction D1 and the second direction D2 by the above-mentioned design of the first spacer PS1 and the second spacer PS2.

As shown in FIG. 1, in some embodiments, in the top view of the display device 1, the first spacer PS1 and the second spacer PS2 are arranged along the third direction D3, and the second acute angle θ2 between the second direction D2 and the third direction D3 is, for example, in a range of 40 degrees to 50 degrees, but the present disclosure is not limited thereto. For example, the second acute angle θ2 may be greater than or equal to 40 degrees and less than or equal to 50 degrees, for example, the second acute angle θ2 may be 40 degrees, 42 degrees, 44 degrees, 46 degrees, 48 degrees, 50 degrees, or any value or range of values between the aforementioned values, but the present disclosure is not limited thereto. In some embodiments, the second acute angle θ2 may be about half of the included angle θ, but the present disclosure is not limited thereto. In some embodiments, the first acute angle θ1 and the second acute angle θ2 may be substantially the same. Accordingly, the first spacer PS1 and the second spacer PS2 may provide support effect in different directions of the first direction D1 and the second direction D2.

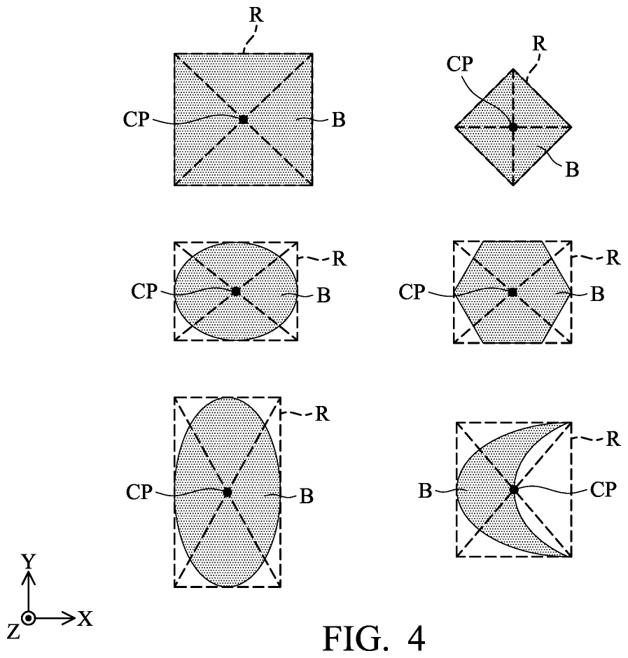

In detail, with reference to FIG. 1 and FIG. 4, when a component and another component described herein are “arranged along a direction”, the term means that the direction is a connection direction of a center of the component and a center of other component. Also, when “arranging direction” of a component and another component described herein are describe, the term means that the arranging direction is a connection direction of a center of the component and a center of other component. For example, the first direction D1 is the connection direction of the center of the first light emitting unit B and the center of the second light emitting unit A, and the second direction D2 is the connection direction of the center of the first light emitting unit B and the center of the third light emitting unit C. For example, the third direction D3 is the arranging direction of the center of the first spacer PS1 and the center of the second spacer PS2.

FIG. 4 shows a schematic view of the centers of different light emitting units according to some embodiments of the present disclosure. As shown in FIG. 4, the first light emitting unit B with different shapes is used as an example for illustration. However, the center of the second light emitting unit A, the third light emitting unit C, the fourth light emitting unit D, the fifth light emitting unit E, the first spacer PS1 and/or the second spacer PS2 is similarly defined. As shown in FIG. 4, in some embodiments, when the first light emitting unit B is a rectangle, the smallest rectangle R that may cover the entire first light emitting unit B is framed. The intersection point of the diagonals of the smallest rectangle R is defined as the center CP of the first light emitting unit B. As shown in FIG. 4, in some other embodiments, when the first light emitting unit B is in the shape of a horizontal ellipse, a vertical ellipse, a rhombus, a hexagon, or a moon shape, in a similar manner, the smallest rectangle R covering the entire first light emitting unit B is framed. Then, the intersection point of the diagonals of the smallest rectangle R is defined as the center CP of the first light emitting unit B, but the present disclosure is not limited thereto.

Referring to FIG. 1 and FIG. 2, in some embodiments, the direction of the first long axis of the first spacer PS1 may be substantially parallel to the arranging direction of the first light emitting unit B and the second light emitting unit A (for example, the first direction D1), so the area of the first spacer PS1 may be flexibly increased without affecting the area of the opening region of the pixel defining layer. Moreover, the direction of the second long axis of the second spacer PS2 may be substantially parallel to the arranging direction of the first light emitting unit B and the third light emitting unit C (for example, the second direction D2), so the area of the second spacer PS2 may be flexibly increased without affecting the area of the opening region of the pixel defining layer. Accordingly, the area for supporting the mask may be increased by increasing the area of the first spacer PS1 and/or the second spacer PS2, thereby reducing the wrinkles of the mask and/or increasing the flatness of the mask. In some embodiments, the first direction D1 and the second direction D2 may be substantially perpendicular to each other.

FIG. 5A shows a schematic top view of a display device 3 according to some embodiments of the present disclosure. For the convenience of description, the same or similar elements will not be repeated. As shown in the schematic top view of FIG. 5A, in some embodiments, the area of the first spacer PS1 may be greater than the area of the second spacer PS2 in the display device 3, but the present disclosure is not limited thereto. In some embodiments, the ratio of the area of the first spacer PS1 to the area of the second spacer PS2 (area of the first spacer PS1/area of the second spacer PS2) may be greater than or equal to 1 and less than or equal to 10, but the present disclosure is not limited thereto. For example, the ratio of the area of the first spacer PS1 to the area of the second spacer PS2 may be 1, 1.25, 1.5, 1.75, 2, 4, 6, 8, 10, or any value or range of values between the aforementioned values, but the present disclosure is not limited thereto.

FIG. 5B is schematic cross-sectional views of the display device 3 taken along section line III-III′ and section line IV-IV′ according to some embodiments of the present disclosure.

As shown in FIG. 5B, in some embodiments, the display device 3 may further include a transistor TFT, a planarization layer PNL, a bottom electrode BE, a pixel defining layer PDL, and/or a top electrode TE, but the present disclosure is not limited thereto. In some embodiments, the transistor TFT may be disposed on the substrate SB. The transistor TFT may include a driving transistor, a switching transistor, the like, or a combination thereof, but the present disclosure is not limited thereto. In some embodiments, the transistor TFT may include an insulating layer (not shown), a source electrode (not shown), a drain electrode (not shown) and a gate electrode (not shown).

In some embodiments, the planarization layer PNL may be disposed on the transistor TFT and the substrate SB to provide a flat surface. In some embodiments, the planarization layer PNL may include an insulating material (such as an organic insulating material). The insulating material is, for example, oxide such as silicon oxide, nitride such as silicon nitride, oxynitride such as silicon oxynitride, other suitable materials, or a combination thereof, but the present disclosure is not limited thereto.

In some embodiments, the pixel defining layer PDL may be disposed on the substrate SB, specifically, the pixel defining layer PDL may be disposed on the planarization layer PNL. In some embodiments, the pixel defining layer PDL may have a plurality of openings O, and the light emitting layer EL may be disposed in the openings O of the pixel defining layer PDL, and the openings O of the pixel defining layer PDL may define a range of plurality of light emitting units, but the present disclosure is not limited thereto. In other words, the size of the light emitting unit (such as the aforementioned light emitting unit) is defined by the size of the opening O of the pixel defining layer PDL. In some embodiments, the light emitting layer EL is driven to emit light by the potential difference provided by the bottom electrode BE and the top electrode TE. In some embodiments, the light emitting layers EL located in the different openings O of pixel defining layers PDL may, for example, not be connected to each other. At this time, the light emitting layers EL in the light emitting units corresponding to different colors may, for example, respectively emit light with different colors, but the present disclosure is not limited thereto. In other embodiments (not shown), the light emitting layers EL in the light emitting units corresponding to different colors may, for example, emit light with the same color. Also, for example, a light conversion layer (not shown) and/or a color filter layer (not shown) may be disposed above the light emitting layers EL. The light conversion layer may include, for example, quantum dot materials, phosphorescent materials, fluorescent materials, or other suitable materials.

In some embodiments (not shown), the light emitting layers EL located in the different openings O of pixel defining layers PDL may, for example, be connected with each other. In some embodiments (not shown), the light emitting layer EL is, for example, the entire layer, and the light emitting layer EL may be located in the different openings O of pixel defining layers PDL at the same time, and the entire layer of the light emitting layer EL may, for example, emit a light with a color (such as blue, but the present disclosure is not limited thereto). In the above situation, the light emitting units corresponding to different colors share the light emitting layer EL, but the light emitting units of different colors may, for example, further include a light conversion layer (not shown) and/or a color filter layer (not shown).

In some embodiments, the bottom electrode BE may be disposed on the planarization layer PNL, and the bottom electrode BE may be electrically connected to the transistor TFT through an opening (not shown) in the planarization layer PNL. In some embodiments, the light emitting layer EL may be disposed on the bottom electrode BE. In some embodiments, the top electrode TE may be disposed on the light emitting layer EL and the pixel defining layer PDL.

As shown in FIG. 5B, in some embodiments, the size of the light emitting unit (such as the aforementioned light emitting unit) is defined by the size of the opening of the pixel defining layer PDL. In some embodiments, the size of the first light emitting unit B may be substantially equal to the size of the second light emitting unit A. In some embodiments, the size of the fourth light emitting unit D may be less than the size of the fifth light emitting unit E, but the present disclosure is not limited thereto. In some embodiments, the first spacer PS1 and the second spacer PS2 may be disposed on the pixel defining layer PDL, specifically, the first spacer PS1 and the second spacer PS2 may be disposed on the top electrode TE.

As shown in FIG. 5B, in some embodiments, along the normal direction of the substrate SB (for example, the Z-axis direction), the first distance h1 between the bottom surface of the pixel defining layer PDL and the top surface of the first spacer PS1 is different from the second distance h2 between the bottom surface of the pixel defining layer PDL and the top surface of the second spacer PS2. In some embodiments, the pixel defining layer PDL may have a uniform height in the normal direction of the substrate SB. In some embodiments, in the normal direction of the substrate SB, the height of the first spacer PS1 may be different from the height of the second spacer PS2, thereby reducing the height variation between different spacers. In other words, the spacer with a lower height may provide a buffer height, thereby reducing the wrinkle of the mask FMM, and/or increasing the flatness of the mask FMM. Thus, the probability of scratching of the light emitting unit by the mask FMM is reduced.

In some embodiments, the difference between the first distance h1 and the second distance h2 (|(first distance h1−second distance h2)|) may be greater than 0 and less than or equal to 1 um, but the present disclosure is not limited thereto. For example, the difference between the first distance h1 and the second distance h2 may be 0.1 um, 0.2 um, 0.3 um, 0.4 um, 0.5 μm, 0.6 um, 0.7 um, 0.8 um, 0.9 um, 1 um, or any value or range of values between the aforementioned values, but the present disclosure is not limited thereto. In some embodiments, the first distance h1 may be greater than 0 and less than or equal to 5 um, but the present disclosure is not limited thereto. For example, the first distance h1 may be 1 um, 2 um, 3 um, 4 um, 5 um, or any value or range of values between the aforementioned values, but the present disclosure is not limited thereto. In some embodiments, the second distance h2 may be greater than 0 and less than or equal to 4 um, but the present disclosure is not limited thereto. For example, the second distance h2 may be 1 um, 2 um, 3 um, 4 um, or any value or range of values between the aforementioned values, but the present disclosure is not limited thereto.

FIG. 6 shows a schematic top view of a display device 4 according to some embodiments of the present disclosure. As shown in FIG. 6, in some embodiments, the display device 4 may further include a third spacer PS3 and a fourth spacer PS4. In some embodiments, the third spacer PS3 and/or the fourth spacer PS4 may be disposed on the substrate SB, and the third spacer PS3 and the fourth spacer PS4 may be disposed on the top electrode TE as shown in FIG. 5B.

As shown in FIG. 6, in some embodiments, in the top view of the display device 4, the first spacer PS1, the second spacer PS2, the third spacer PS3, and the fourth spacer PS4 are arranged along the third direction D3. In other words, the connection direction of the centers of the first spacer PS1, the second spacer PS2, the third spacer PS3, and the fourth spacer PS4 is the third direction D3. As shown in FIG. 6, in some embodiments, the third direction D3 is different from the first direction D1. In some embodiments, the third direction D3 is different from the second direction D2.

In some embodiments, in the top view of the display device 4, the area of the first spacer PS1 may be greater than the area of the second spacer PS2, and the area of the third spacer PS3 may be greater than the area of the fourth spacer PS4. Accordingly, the spacers with different areas are arranged alternately (for example, along the third direction D3), so the pressure of the mask FMM may be evenly distributed on the spacers. In detail, the area of the first spacer PS1 may be greater than the area of the second spacer PS2, the area of the second spacer PS2 may be less than the area of the third spacer PS3, and the area of the third spacer PS3 may be greater than the area of the fourth spacer PS4.

In some embodiments, the area of the first spacer PS1 and the area of the third spacer PS3 may be substantially the same, but the present disclosure is not limited thereto. In some embodiments, the area of the second spacer PS2 and the area of the fourth spacer PS4 may be substantially the same, but the present disclosure is not limited thereto. In some embodiments, the ratio of the area of the first spacer PS1 to the area of the second spacer PS2 (area of the first spacer PS1/area of the second spacer PS2) may be greater than or equal to 1 and less than or equal to 10, but the present disclosure is not limited thereto. For example, the ratio of the area of the first spacer PS1 to the area of the second spacer PS2 may be 1, 1.25, 1.5, 1.75, 2, 4, 6, 8, 10, or any value or range of values between the aforementioned values, but the present disclosure is not limited thereto. In some embodiments, the ratio of the area of the third spacer PS3 to the area of the fourth spacer PS4 (area of the third spacer PS3/area of the fourth spacer PS4) may be greater than or equal to 1 and less than or equal to 10, but the present disclosure is not limited thereto. For example, the ratio of the area of the third spacer PS3 to the area of the fourth spacer PS4 may be 1, 1.25, 1.5, 1.75, 2, 4, 6, 8, 10, or any value or range of values between the aforementioned values, but the present disclosure is not limited thereto.

As shown in FIG. 6, in some embodiments, the first long axis of the first spacer PS1 may be substantially parallel to the first direction D1, and the second long axis of the second spacer PS2 may be substantially parallel to the second direction D2, the third long axis of the third spacer PS3 may be substantially parallel to the second direction D2, and the fourth long axis of the fourth spacer PS4 may be substantially parallel to the first direction D1. In some embodiments, the direction of the first long axis of the first spacer PS1 is different from the direction of the third long axis of the third spacer PS3, and the direction of the second long axis of the second spacer PS2 is different from the direction of the fourth long axis of the fourth spacer PS4. In some embodiments, when there is an odd number of intervals PS0 between the second spacer PS2 and the third spacer PS3, the direction of the second long axis of the second spacer PS2 is the same as the direction of the third long axis of the third spacer PS3. For example, the aforementioned odd number of intervals PS0 may be 1, 3, 5, 7, 9, or another odd number. Accordingly, the mask may flexibly increase the area of the spacers without reducing the area of the light emitting unit.

In other embodiments, referring to FIG. 1, in some embodiments, the first long axis of the first spacer PS1 is parallel to the first direction D1, the second long axis of the second spacer PS2 is parallel to the second direction D2, the third long axis of the third spacer PS3 (not shown) is parallel to the first direction D1, and the fourth long axis of the fourth spacer PS4 (not shown) is parallel to the second direction D2. In other words, the direction of the first long axis of the first spacer PS1 is the same as the direction of the third long axis of the third spacer PS3, and the direction of the second long axis of the second spacer PS2 is the same as the direction of the fourth long axis of the fourth spacer PS4. In some embodiments, when there is an even number of intervals PS0 between the second spacer PS2 and the third spacer PS3 or there is no interval PS0 between the second spacer PS2 and the third spacer PS3, the direction of the second long axis of the second spacer PS2 may be different from the direction of the third long axis of the third spacer PS3. The aforementioned even number of intervals PS0 includes 0, 2 (as shown in FIG. 1), 4, 6, 8, or another even number. Accordingly, the area of the spacers may be flexibly increased without reducing the area of the light emitting unit.

As shown in FIG. 6, in some embodiments, the display device 4 may include at least four spacers arranged sequentially along a direction. For example, the display device 4 may include a first spacer PS1, a second spacer PS2, a third spacer PS3, and a fourth spacer PS4 arranged in sequence along the third direction D3. The long axes of the two spacers in the middle (for example, the second long axis of the second spacer PS2 and the third long axis of the third spacer PS3) are in the same direction, and the long axes of the two spacers on the two sides (for example, the first long axis of the first spacer PS1 and the fourth long axis of the fourth spacer PS4) are in different directions than the long axes of the two spacers in the middle. For example, the second long axis of the second spacer PS2 and the third long axis of the third spacer PS3 are both in the second direction D2, the first long axis of the first spacer PS1 and the fourth long axis of the fourth spacer PS4 are both in the first direction D1, and the first direction D1 is different from the second direction D2, but the present disclosure is not limited thereto. In some embodiments, the included angle between the first direction D1 and the second direction D2 may be greater than or equal to 80 degrees and less than or equal to 100 degrees, but the present disclosure is not limited thereto. Accordingly, an appropriate area of the spacer may be maintained without affecting or reducing the area of the light emitting unit.

FIG. 7 shows a schematic top view of a display device 5 according to some embodiments of the present disclosure. As shown in FIG. 7, in some embodiments, the display device 5 may further include a third spacer PS3 and a fourth spacer PS4. In some embodiments, the area of the first spacer PS1 may be greater than the area of the second spacer PS2, and the area of the third spacer PS3 may be greater than the area of the fourth spacer PS4, but the present disclosure is not limited thereto. In some embodiments, the area of the first spacer PS1 (or the area of the third spacer PS3) may be greater than or equal to the area of the first light emitting unit B, the second light emitting unit A, and/or the third light emitting unit C, but the present disclosure is not limited thereto. In some embodiments, the area of the second spacer PS2 (or the area of the fourth spacer PS4) may be less than or equal to the area of the first light emitting unit B, the second light emitting unit A, and/or the third light emitting unit C, but the present disclosure is not limited thereto. The areas of the spacers mentioned above may be adjusted according to requirements.

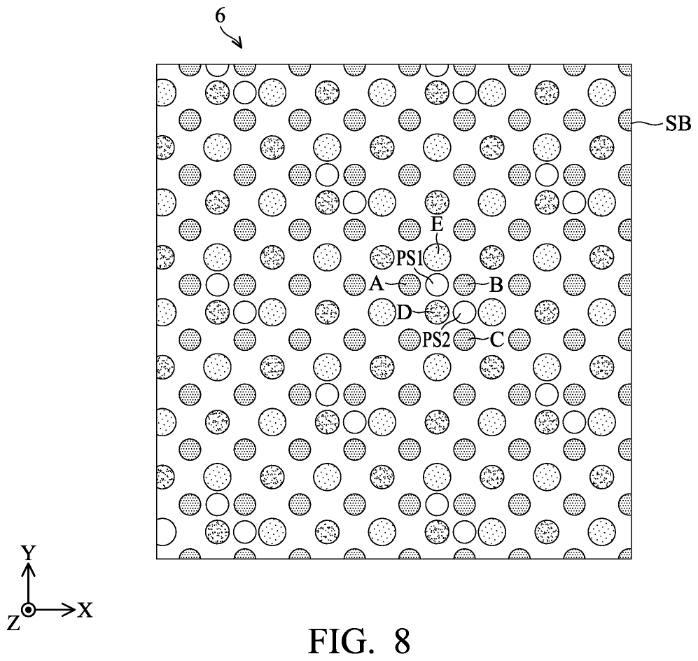

FIG. 8 shows a schematic top view of a display device 6 according to some embodiments of the present disclosure. As shown in FIG. 8, in some embodiments, the first light emitting unit B, the second light emitting unit A, the third light emitting unit C, the fourth light emitting unit D, the fifth light emitting unit E, the first spacer PS1, and the second spacer PS2 may have a circular shape, but the present disclosure is not limited thereto. As shown in FIG. 8, in some embodiments, in the top view of the display device 6, the area of the first light emitting unit B, the area of the second light emitting unit A, and the area of the third light emitting unit C may be substantially the same. In some embodiments, in the top view of the display device 6, the area of the first light emitting unit B may be less than the area of the fourth light emitting unit D, and the area of the fourth light emitting unit D may be less than the area of the fifth light emitting unit E. In some embodiments, the areas of the first spacer PS1 and the second spacer PS2 may be the same or different. In some embodiments, in a top view of the display device, the shape of the first spacer PS1 and/or the second spacer PS2 may be circular. In some embodiments, the area of the first spacer PS1 (or the area of the second spacer PS2) may be the same as or different from the area of the first light emitting unit B, the second light emitting unit A, and/or the third light emitting unit C. In some embodiments, the area of the first spacer PS1 (or the area of the second spacer PS2) may be greater than the area of the first light emitting unit B, the second light emitting unit A, and/or the third light emitting unit C. In some embodiments, the area of the first spacer PS1 (or the area of the second spacer PS2) may be less than the area of the first light emitting unit B, the second light emitting unit A, and/or the third light emitting unit C. The areas of the spacers mentioned above may be adjusted according to requirements.

In some embodiments, the display devices 1, 2, 3, 4, 5, and/or 6 of the present disclosure may be applied to consumer electronics such as mobile phones and tablet computers.

In summary, according to the embodiments of the present disclosure, a display device is provided. By disposing the first spacer and the second spacer and their specific arrangement, the supporting area of the metal mask and/or the supporting uniformity may be increased. Therefore, the first spacer and the second spacer may reduce the problem of wrinkles caused by thermal expansion of the metal mask, thereby improving the flatness of the metal mask. Accordingly, the electrical performance and/or reliability of the display device may be improved and/or the precision of the manufacturing process of the display device may be improved.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A display device, comprising:
a substrate;
a first light emitting unit, a second light emitting unit, and a third light emitting unit disposed on the substrate and configured to emit a first light with a first color respectively, wherein the first light emitting unit is adjacent to the second light emitting unit and the third light emitting unit;
a first spacer disposed on the substrate; and
a second spacer disposed on the substrate;
wherein in a top view of the display device, the first spacer is disposed between the first light emitting unit and the second light emitting unit,
the second spacer is disposed between the first light emitting unit and the third light emitting unit, an extending line of a first long axis of the first spacer passes through the first light emitting unit and the second light emitting unit, and an extending line of a second long axis of the second spacer passes through the first light emitting unit and the third light emitting unit.

2. The display device of claim 1, further comprising:
a fourth light emitting unit, disposed on the substrate and configured to emit a second light with a second color; and
a fifth light emitting unit, disposed on the substrate and configured to emit a third light with a third color;
wherein in the top view of the display device, an area of the first light emitting unit is less than an area of the fourth light emitting unit, and the area of the first light emitting unit is less than an area of the fifth light emitting unit.

3. The display device of claim 1, wherein a minimum distance between the first spacer and the second spacer is less than a minimum distance between the first light emitting unit and the second light emitting unit in the top view of the display device.

4. The display device of claim 3, wherein the minimum distance between the first spacer and the second spacer is greater than 0 and less than 20 um.

5. The display device of claim 1, wherein in the top view of the display device, the first light emitting unit and the second light emitting unit are arranged along a first direction, and the first light emitting unit and the third light emitting unit are arranged along a second direction different from the first direction.

6. The display device of claim 5, wherein an included angle between the first direction and the second direction is in a range from 80° to 100°.

7. The display device of claim 5, wherein in the top view of the display device, the first spacer and the second spacer are arranged along a third direction, and a first acute angle between the first direction and the third direction is in a range from 40° to 50°.

8. The display device of claim 1, further comprising:
a pixel defining layer, disposed on the substrate;
wherein the first spacer and the second spacer are disposed on the pixel defining layer, a first distance between a bottom surface of the pixel defining layer and a top surface of the first spacer is different from a second distance between the bottom surface of the pixel defining layer and a top surface of the second spacer along a normal direction of the substrate.

9. The display device of claim 8, wherein a difference between the first distance and the second distance is greater than 0 and less than or equal to lum.

10. The display device of claim 1, further comprising a third spacer and a fourth spacer disposed on the substrate,
wherein in the top view of the display device, the first spacer, the second spacer, the third spacer, and the fourth spacer are arranged along a third direction, an area of the first spacer is greater than an area of the second spacer, and an area of the third spacer is greater than an area of the fourth spacer.

11. The display device of claim 10, wherein a direction of the first long axis of the first spacer is different from a direction of a third long axis of the third spacer, and a direction of the second long axis of the second spacer is different from a direction of a fourth long axis of the fourth spacer.

12. The display device of claim 11, wherein there is an odd number of intervals between the second spacer and the third spacer.

13. The display device of claim 10, wherein a direction of the first long axis of the first spacer is the same as a direction of a third long axis of the third spacer, and a direction of the second long axis of the second spacer is the same as a direction of a fourth long axis of the fourth spacer.

14. The display device of claim 13, wherein there is an even number of intervals between the second spacer and the third spacer.

15. The display device of claim 10, wherein the area of the second spacer is less than the area of the third spacer.

16. The display device of claim 1, wherein a long axis of the first light emitting unit is different from a long axis of the second light emitting unit, and the long axis of the second light emitting unit is the same as a long axis of the third light emitting unit.

17. The display device of claim 1, wherein an area of the first spacer is greater than an area of the second spacer.

18. The display device of claim 17, wherein a ratio of the area of the first spacer to the area of the second spacer is greater than or equal to 1 and less than or equal to 10.

19. The display device of claim 1, wherein a minimum distance between the first spacer and the second spacer is less than a minimum distance between the first light emitting unit and the third light emitting unit in the top view of the display device.

20. A display device, comprising:
a substrate;
a first light emitting unit, a second light emitting unit, and a third light emitting unit disposed on the substrate and configured to emit a light with a first color respectively, wherein the first light emitting unit is adjacent to the second light emitting unit and the third light emitting unit;
a first spacer disposed on the substrate; and
a second spacer disposed on the substrate;
wherein in a top view of the display device, the first spacer is disposed between the first light emitting unit and the second light emitting unit,
the second spacer is disposed between the first light emitting unit and the third light emitting unit, the first light emitting unit and the second light emitting unit are arranged along a first direction, and the first light emitting unit and the third light emitting unit are arranged along a second direction different from the first direction.
